(19) United States
(12) Patent Application Publication
(10) Pub. No.: US 2013/0134126 A1
(43) Pub. Date: May 30, 2013

(54) REDUCING DEFECTS IN ELECTRONIC APPARATUS

(71) Applicants: Dorota Kowal-Paul, Langebrueck (DE); Enrico Bellmann, Dresden (DE); Oisin Kenny, Dresden (DE); Stefan Ruckmich, Dresden (DE)

(72) Inventors: Dorota Kowal-Paul, Langebrueck (DE); Enrico Bellmann, Dresden (DE); Oisin Kenny, Dresden (DE); Stefan Ruckmich, Dresden (DE)

(73) Assignee: PLASTIC LOGIC LIMITED, Cambridge (GB)

(21) Appl. No.: 13/701,788

(22) PCT Filed: Jun. 3, 2011
(86) PCT No.: PCT/EP11/59216

§ 371 Date: Feb. 13, 2013

(30) Foreign Application Priority Data
Jun. 4, 2010 (GB) 1009400.1

(51) Int. Cl. H05K 13/00

(52) U.S. Cl. CPC H05K 13/00
USPC 216/13; 156/345.1

(57) ABSTRACT

A technique, comprising defining at least part of one or more electronic devices on a substrate sheet by means of one or more material removal processes, wherein the substrate sheet is arranged on a lower layer so as to overhang said lower layer more at a first end than it does at an opposite, second end; and removing loose material from under said overhang at said first end by means of a stream of gas directed at said substrate and said lower layer from an outlet, said stream of gas having at said outlet at least a directional component parallel to a direction from said second end to said first end.

The present invention relates to a technique for reducing the occurrence of defects in the production of electronic apparatus, such an electronically controlled display apparatus.

One technique used in the mass-production of electronic apparatus involves temporarily securing a sheet of device material to a processing support, carrying out processing steps on one or more regions of an upper surface of the device substrate material sheet to form one or more devices, and later removing the one or more devices (including their respective portions of the device substrate material sheet) from the processing support after completion of said substrate processing steps.

Processing of the device substrate material sheet typically includes photolithography and etching steps to form a patterned layer of material on an upper surface of the substrate sheet. The patterned layer may, for example, be a patterned metal layer that defines the conductive elements (e.g. electrodes and/or addressing lines) at one level of an array of electronic devices (e.g. transistors) of an electronic apparatus.

The substrate sheet is secured to the common support via an adhesive layer. The adhesive layer is arranged such that it is more than completely covered by the substrate sheet (i.e. each side of the substrate sheet overhangs a respective side of the adhesive layer) with the aim of preventing exposure of the adhesive layer to the radiation and/or chemicals (e.g. etchants/resists) used during the substrate processing steps.

The inventors have observed an increased number of defects for the above-described kind of production method compared to the kind of production method where the substrate sheet is not temporarily adhered to a lower processing support during the substrate processing steps. The observed increase in defects is attributable to an increase in what have been identified by the inventors as defects caused by materials used in the substrate processing steps.

It is an aim of the present invention to provide a technique for reducing the number of defects in the above-mentioned kind of production method.

The present invention provides a method comprising: defining at least part of one or more electronic devices on a substrate sheet by means of one or more material removal processes, wherein the substrate sheet is arranged on a lower layer so as to overhang said lower layer more at a first end than it does at an opposite, second end; and removing loose material from under said overhang at said first end by means of a stream of gas directed at said substrate and said lower layer from an outlet, said stream of gas having at said outlet at least a directional component parallel to a direction from said second end to said first end.

In one embodiment, said stream of gas is directed substantially in a direction from said second end to said first end.

In one embodiment, the method further comprises peeling at least a portion of said substrate sheet away from said lower layer starting at said second end.

In one embodiment, the substrate sheet is arranged on said lower layer via one or more further layers.

In one embodiment, the lower layer is an adhesive element that releaseably secures the substrate sheet to a support structure.

The present invention also provides a method, comprising: defining at least part of one or more electronic devices on a substrate sheet by means of one or more material removal processes, wherein the substrate sheet is arranged on a support structure via a lower layer so as to overhang said lower layer more at a first end than it does at an opposite, second end; and removing loose material from under said overhang at said first end by means of a stream of gas directed over said support structure from an outlet, said stream of gas having at said outlet at least a directional component parallel to a direction from said second end to said first end.

In one embodiment, said stream of gas is directed substantially in a direction from said second end to said first end.

In one embodiment, the method further comprises peeling at least a portion of said substrate sheet away from said lower layer starting at said second end.

In one embodiment, said substrate sheet is arranged on said support structure via a stack of layers including said lower layer.

In one embodiment, the lower layer is an adhesive element that releaseably secures the substrate sheet to said support structure.

In one embodiment, the substrate sheet provides a plurality of device substrates for a plurality of devices.

The present invention also provides apparatus configured to carry out the method of the present invention. In one embodiment, the apparatus is configured to rotate said substrate sheet into a position in which said second end faces said outlet.

Hereunder is provided, by way of example only, a detailed description of an embodiment of the present invention with reference to the accompanying drawings, in which:

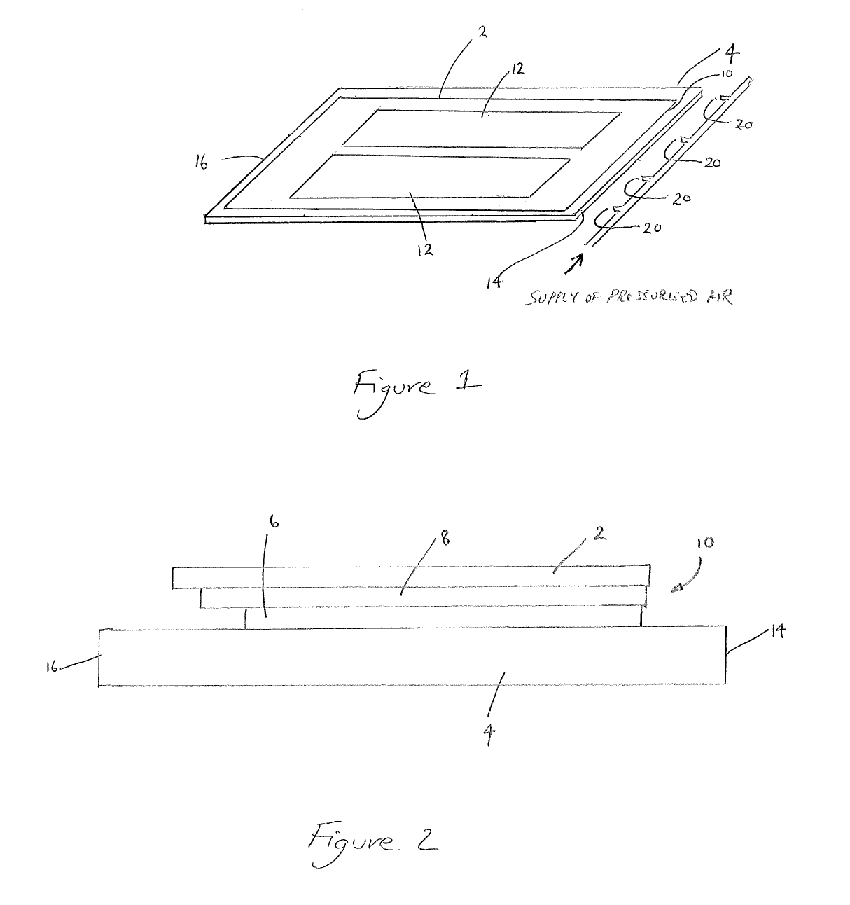

FIG. 1 illustrates a sheet of device substrate material temporarily adhered to a glass motherplate in preparation for the substrate processing steps; and

FIG. 2 illustrates the layers provided between the device material substrate sheet and the glass motherplate.

As shown in FIG. 1, a sheet 2 of plastic substrate material is temporarily adhered to a glass motherplate 4. The sheet of plastic substrate material 2 provides device substrates for a plurality of devices. The regions of the substrate sheet that will form the plurality of device substrates in the final products are designated by reference numerals 12 in FIG. 1. FIG. 1 shows the simple example where the substrate sheet 2 provides two device substrates, but larger numbers are possible and advantageous from the point of view of achieving an efficient production process. The substrate material sheet 2 is cut at a later stage of the productions process after processing of the substrate sheet 2 is completed. The plastic substrate sheet 2 is made of Heat-Stabilised Polyethylene Terephthalate (HSPET). As shown in FIG. 2, the plastic substrate sheet 2 is temporarily adhered to the glass motherplate 4 via an adhesive element 6, and an intermediary barrier element 8. The adhesive element 6 comprises a base material with adhesives on opposing faces thereof. The barrier element comprises an inorganic ceramic film. The substrate sheet 2 is provided with a planarization layer (not shown) over the entire area of the upper surface thereof.

The barrier element 8 and the adhesive element 6 are sized and arranged such that the substrate sheet 2 overlaps both the barrier element 8 and adhesive patch 6 on all four sides, but with a relatively small volume of overlap on only one side 10 of the four sides. Although a smaller volume of overlap is less beneficial from the point of view of preventing exposure of the adhesive element 6 to radiation and/or chemicals used in the subsequent substrate processing steps of the kind described below, the provision of one edge 10 with a relatively small volume of overlap has been found to be beneficial from the point of view of facilitating the later delamination of the plastic substrate material from the glass motherplate 4. The edge 10 with the smallest volume of overlap I faces towards edge 14 of the motherplate 4 in FIG. 1.

The plastic substrate sheet 2 provides the bases for respective arrays of field effect transistors used to control a respective array of display pixels in the finished products. The device regions 12 of the substrate sheet 2 temporarily adhered to the motherplate 4 are subject to the following processing steps. Thin blanket layers of titanium and gold (not shown) are consecutively deposited over the entire area of the upper surface of the planarization layer by a physical vapour deposition process such as sputtering. A blanket layer of photoresist material is next deposited over the entire area of the upper surface of said metal layers. Next, photolithographic and etching techniques are used to remove selected portions of the resist layer and the underlying metal layers to create a metal pattern in each of the device regions 12. This metal pattern defines the electrodes and/or signal/addressing lines at one level of said array of transistors, which array of transistors are completed by subsequent processing steps carried out at a later stage of the production method, such as the formation of a semiconductor layer, a gate dielectric layer and a further patterned metal layer to define an upper level of electrodes and/or signal/addressing lines.

After the completion of the above-described substrate processing steps, one or more streams of air are directed at the substrate sheet 2 on the motherplate 4 from one or more air outlets 20 arranged to the side of the edge 14 of the motherplate 4 towards which face the edge 10 of the substrate sheet having the smaller volume of overlap. The streams of air are caused to flow over the surface of the motherplate 4 in a direction from said edge 14 of the motherplate to the opposing edge 16 of the motherplate 4. This direction is shown by the arrows in FIG. 1.

It has been found that this use of a gas stream results in about 50% fewer defects compared to the case where the same gas stream is caused to flow over the motherplate 4 in the opposite direction. Where the construction of the processing apparatus dictates that earlier steps (such as the above-described substrate processing steps) are carried out with an edge of the motherplate 4 other than said edge 14 located closest to the gas stream outlet 20, the motherplate 4 is rotated after the completion of said earlier steps into a position in which said edge 14 of the motherplate 4 is located closest of all four edges to the gas stream outlet 20.

The reduction in defects is attributed to the effect of the gas stream in moving loose material (such as stripper/etchant residue from the substrate processing steps) from under the overhangs to a location from which it is not carried off with the device substrates upon cutting and delamination of the device substrates from the motherplate 4.

In addition to any modifications explicitly mentioned above, it will be evident to a person skilled in the art that various other modifications of the described embodiment may be made within the scope of the invention.

1. A method, comprising defining at least part of one or more electronic devices on a substrate sheet by means of one or more material removal processes, wherein the substrate sheet is arranged on a lower layer so as to overhang said lower layer more at a first end than it does at an opposite, second end; and removing loose material from under said overhang at said first end by means of a stream of gas directed at said substrate and said lower layer from an outlet, said stream of gas having at said outlet at least a directional component parallel to a direction from said second end to said first end.

2. The method according to claim 1, wherein said stream of gas is directed substantially in a direction from said second end to said first end.

3. The method according to claim 1, further comprising peeling at least a portion of said substrate sheet away from said lower layer starting at said second end.

4. The method according to claim 1, wherein said substrate sheet is arranged on said lower layer via one or more further layers.

5. A method according to claim 1, wherein the lower layer is an adhesive element that releaseably secures the substrate sheet to a support structure.

6. The method, comprising defining at least part of one or more electronic devices on a substrate sheet by means of one or more material removal processes, wherein the substrate sheet is arranged on a support structure via a lower layer so as to overhang said lower layer more at a first end than it does at an opposite, second end; and removing loose material from under said overhang at said first end by means of a stream of gas directed over said support structure from an outlet, said stream of gas having at said outlet at least a directional component parallel to a direction from said second end to said first end.

7. The method according to claim 6, wherein said stream of gas is directed substantially in a direction from said second end to said first end.

8. The method according to claim 6, further comprising peeling at least a portion of said substrate sheet away from said lower layer starting at said second end.

9. The method according to claim 6, wherein said substrate sheet is arranged on said support structure via a stack of layers including said lower layer.

10. The method according to claim 6, wherein the lower layer is an adhesive element that releaseably secures the substrate sheet to said support structure.

11. The method according to claim 1, wherein the substrate sheet provides a plurality of device substrates for a plurality of devices.

12. Apparatus configured to carry out the method of claim 1.

13. Apparatus according to claim 12, which is configured to rotate said substrate sheet into a position in which said second end faces said outlet.
